(19) United States
(12) Patent Application Publication
(10) Pub. No.: US 2015/0179818 A1
(43) Pub. Date: Jun. 25, 2015

(54) METHOD OF MANUFACTURING NONVOLATILE SEMICONDUCTOR STORAGE DEVICE AND NONVOLATILE SEMICONDUCTOR STORAGE DEVICE

(71) Applicant: KABUSHIKI KAISHA TOSHIBA, Minato-ku (JP)

(72) Inventor: Yumi OHNO, Nagoya (JP)

(73) Assignee: KABUSHIKI KAISHA TOSHIBA, Minato-ku (JP)

(21) Appl. No.: 14/504,817

(22) Filed: Oct. 2, 2014

(30) Foreign Application Priority Data
Dec. 20, 2013 (JP) 2013-263748

(51) Int. Cl. H01L 29/792; H01L 27/115

(52) U.S. Cl. CPC H01L 29/792; H01L 27/11563; H01L 27/1157

(57) ABSTRACT

A method of nonvolatile semiconductor storage device including forming a tunnel insulating film so as to contact a semiconductor substrate; forming a charge trap layer above the tunnel insulating film including a trap layer configured to trap charge and a block layer configured to block penetration of electrons; forming a control electrode so as to contact the charge trap layer; anisotropically etching the control electrode to expose a sidewall of the control electrode; depositing a deposit so as to be attached to a surface of the sidewall of the control electrode exposed by the etching; and anisotropically etching the charge trap layer using the deposit as a mask so that the charge trap layer projects in a gate-length direction from a lower end of the sidewall of the control electrode and a sidewall of the charge trap layer is exposed.

### CROSS-REFERENCE TO RELATED APPLICATION(S)

This application is based upon and claims the benefit of priority from Japanese Patent Application No. 2013-263748, filed on, Dec. 20, 2013, the entire contents of which are incorporated herein by reference.

### FIELD

Embodiments disclosed herein generally relate to a method of manufacturing a nonvolatile semiconductor storage device and a nonvolatile semiconductor storage device.

### BACKGROUND

Nonvolatile semiconductor storage devices are used in various applications. Nonvolatile semiconductor storage devices are typically provided with a memory cell. With advances in shrinking of semiconductor elements and integration of semiconductor storage devices, a gate structure in which a charge trap layer and a control electrode are stacked above a semiconductor substrate via a tunnel insulating film is being considered for example as the gates of various transistors forming the storage elements. The charge trap layer may include a trap layer configured to trap charge and a block layer configured to block penetration of charge. One of the concerns in employing the charge trap layer, is that its electrical properties may deteriorate when oxidized.

### BRIEF DESCRIPTION OF THE DRAWINGS

FIG. 1 pertains to a first embodiment and is one example of a vertical cross-sectional side surface view schematically illustrating the structure of a nonvolatile semiconductor storage device.

FIGS. 2A, 2B, 2C, 3A, 3B, 30, 4A, 4B, 7A, and 75 are examples of vertical cross-sectional side surface views schematically illustrating the structure of the nonvolatile semiconductor storage device of the first embodiment in one phase of a manufacturing process flow.

FIG. 5 is a chart indicating the relation between the distance from the lateral end of the gate and the thickness of deposits.

FIG. 6 is one example of a vertical cross-sectional side surface view schematically illustrating a comparative example of the first embodiment.

FIG. 8 pertains to a second embodiment and is one example of a circuit diagram schematically illustrating the electrical configuration of the nonvolatile semiconductor storage device.

FIG. 9 pertains to the second embodiment and is one example of a plan view schematically illustrating the structure of a memory-cell region of the nonvolatile semiconductor storage device.

FIG. 10A pertains to the second embodiment and is one example of a vertical cross-sectional side surface view, taken along line 10A-10A of FIG. 9, schematically illustrating the structure of the memory-cell region of the nonvolatile semiconductor storage device.

FIG. 10B pertains to the second embodiment and is one example of a vertical cross-sectional side surface view, taken along line 10B-10B of FIG. 9, schematically illustrating the structure of the memory-cell region of the nonvolatile semiconductor storage device.

FIGS. 11, 12, 13, and 14 are examples of vertical cross-sectional side surface views schematically illustrating the structure of the nonvolatile semiconductor storage device of the second embodiment in one phase of a manufacturing process flow.

### DESCRIPTION

One embodiment of a method of manufacturing a nonvolatile semiconductor storage device includes forming a tunnel insulating film so as to contact a semiconductor substrate; forming a charge trap layer above the tunnel insulating film including a trap layer configured to trap charge and a block layer configured to block penetration of electrons; forming a control electrode so as to contact the charge trap layer; anisotropically etching the control electrode to expose a sidewall of the control electrode; depositing a deposit so as to be attached to a surface of the sidewall of the control electrode exposed by the etching; and anisotropically etching the charge trap layer using the deposit as a mask so that the charge trap layer projects in a gate-length direction from a lower end of the sidewall of the control electrode and a sidewall of the charge trap layer is exposed.

One embodiment of a nonvolatile semiconductor storage device is provided with a semiconductor substrate; and one or more transistors each including: a tunnel insulating film disposed in contact with the semiconductor substrate; a charge trap layer disposed above the tunnel insulating film and formed of a stack including a trap layer configured to trap charge and a block layer configured to prevent penetration of electrons; and a control electrode disposed in contact with the charge trap layer, the charge trap layer of the one or more transistors has a sidewall projecting laterally along a gate-length direction of the control electrode from a lower end of a sidewall of the control electrode located in the gate-length direction.

With reference to the accompanying drawings, embodiments of a method of manufacturing a nonvolatile semiconductor storage device and the manufactured nonvolatile semiconductor storage device are described hereinafter. In the drawings referred to in the following description, elements that are identical or similar are identified with identical or similar reference symbols. The drawings are schematic and thus, are not necessarily consistent with the actual correlation of thickness to planar dimensions and the actual thickness ratios between each of the layers. Further, directional terms such as up, down, left, and right are used in a relative context with an assumption that the surface, on which circuitry is formed, of the later described semiconductor substrate faces up. Thus, the directional terms do not necessarily correspond to the directions based on gravitational acceleration. Further, for convenience of explanation, directional terms such as up, down, left, right, high and low, as well as deep and shallow for describing the trenches are used in a relative context with respect to a rear side of the later described semiconductor substrate.

### First Embodiment

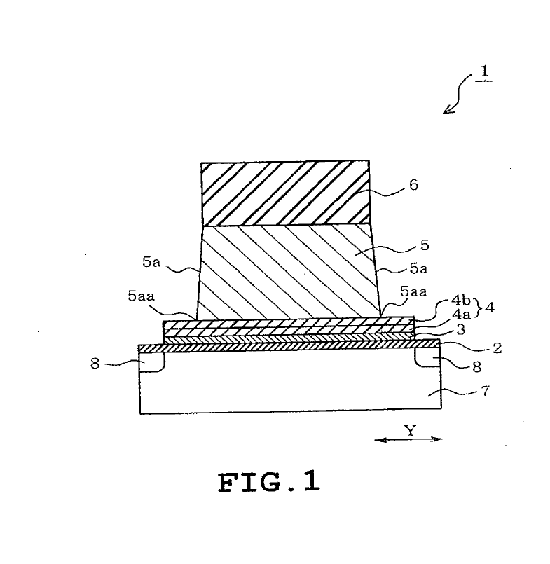

FIG. 1 to FIG. 7 illustrate a first embodiment. The first embodiment will be described through an example of a cell transistor storage element (also referred to as a transistor). The features of the transistor will be described hereinafter. As illustrated in FIG. 1, transistor 1 is configured by a stack of films disposed above a semiconductor substrate 7 (such as a p-type silicon substrate) for example. In the first embodiment, the stack of films include tunnel insulating film 2, polysilicon film 3, charge trap layer 4, control electrode 5, and cap film 6. Further, transistor 1 is provided with diffusion layer 8 formed in the surface layer of semiconductor substrate 7 disposed at both sides of the stack structure.

In the first embodiment, tunnel insulating film 2 is formed in contact with the upper surface of semiconductor substrate 7. Further, polysilicon film 3 is formed in contact with the upper surface of tunnel insulating film 2. Polysilicon film 3 is formed of a polycrystallized silicon doped with n-type (such as phosphorous) and/or a p-type (such as boron) impurities.

Charge trap layer 4 is formed in contact with the upper surface of polysilicon film 3. In the first embodiment, charge trap layer 4 is formed of a stack structure including for example an IFD film comprising a silicon nitride film (SiN), hafnium-containing silicon oxide film (HfSiOx), silicon oxide film (SiO₂), and a hafnium-containing silicon oxide film (HfSiOx). In other words, charge trap layer 4 is formed of a stack of films including the so-called high-dielectric-constant film (High-K film). The stack structure is not limited to the structure exemplified above but may include a high-dielectric-constant film(s) (High-K film) formed of other materials, or at least one of the layers may be replaced by the oxide film.

In the first embodiment, charge trap layer 4 is configured by trap layer 4a and block layer 4b formed in contact with the upper surface of trap layer 4a. Trap layer 4a substantially traps electrons, whereas block layer 4b prevents passing or penetration of charge. The configuration of charge trap layer 4 may be modified depending upon the required functionality and thus, trap layer 4a and block layer 4b are illustrated independently in the drawings.

Control electrode 5 is formed in contact with the upper surface of charge trap layer 4. Control electrode 5 is formed of a stack structure including a barrier metal comprising a tungsten nitride (WN) for example and a metal film comprising tungsten (W). Cap film 6 is formed in contact with the upper surface of control electrode 5. Cap film 6 is formed of a silicon oxide film for example.

Sidewalls 5a of control electrode 5 located on both Y direction (gate-length direction) sides are positively tapered so that the width of control electrode 5 becomes narrower toward the upper side (top) from the lower side (bottom). Charge trap layer 4 projects laterally in the Y direction (gate-length direction) from bottom end 5aa of sidewall 5a of control electrode 5. The sidewalls of charge trap layer 4 are substantially upright. The length of sidewalls of control electrode 5, as viewed for example in the cross section of FIG. 1, is greater than the length of the projections of charge trap layer 4. Further, the area of the sidewalls of control electrode 5 is greater than the area of the upper surface of the projections of charge trap layer 4. Diffusion layers 8 formed at both gate-length direction sides of the stack of structures 2 to 5 serve as source/drain.

In such structure, when electric field is applied between control electrode 5 and semiconductor substrate 7, and charge is transported into charge trap layer 4, charge trap layer 4 traps electrons (charge) and for example blocks the penetration of electrons toward control electrode 5 as much as possible. Accordingly, charge trap layer 4 is configured to include trap layer 4a as well as block layer 4b for preventing the penetration of electrons.

In the above described structure, charge trap layer 4 projects further laterally in the gate-length direction relative to lower end 5aa of sidewall 5a of control electrode 5. Thus, it is possible to increase the volume of charge trap layer 4 and retain its electrical properties as compared to a structure in which the surfaces of the sidewalls of control electrode 5 and charge trap layer 4 are co-planar. For example, even in case a process performing extensive oxidation after the formation of charge trap layer 4 is employed in the manufacturing process flow, it is possible to prevent charge trap layer 4 from being adversely affected by the oxidation process, thereby allowing retention of electrical properties.

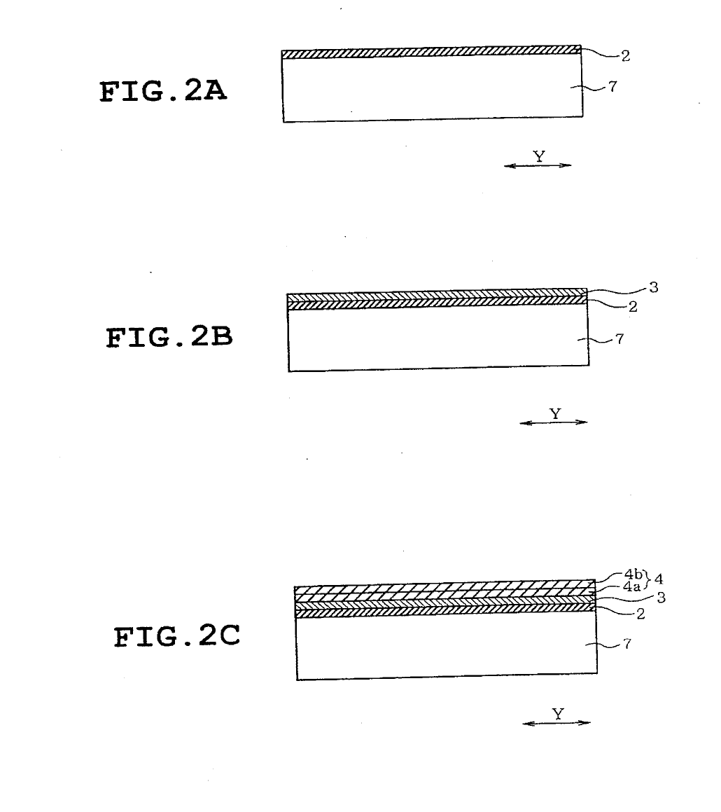

With reference to FIG. 2A to FIG. 7B, a description will be given on one example of a manufacturing process flow of the structure described above. The following description will focus on the features of the first embodiment. However, process steps that are required for implementation or that are known may be further incorporated between the process steps discussed below. Further, the discussed process steps may be rearranged if practicable.

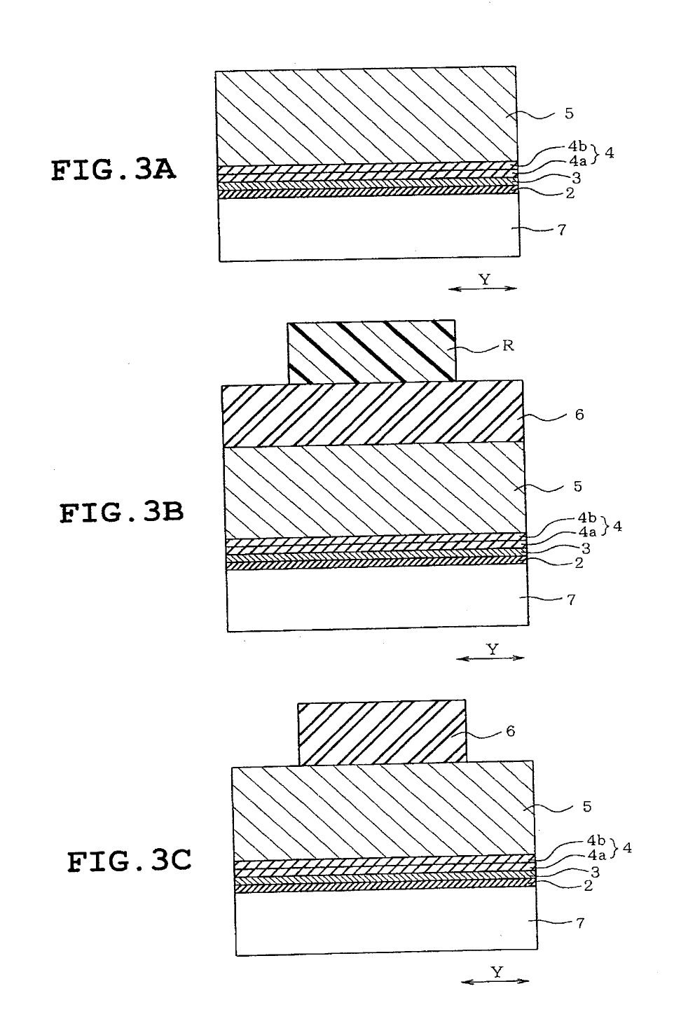

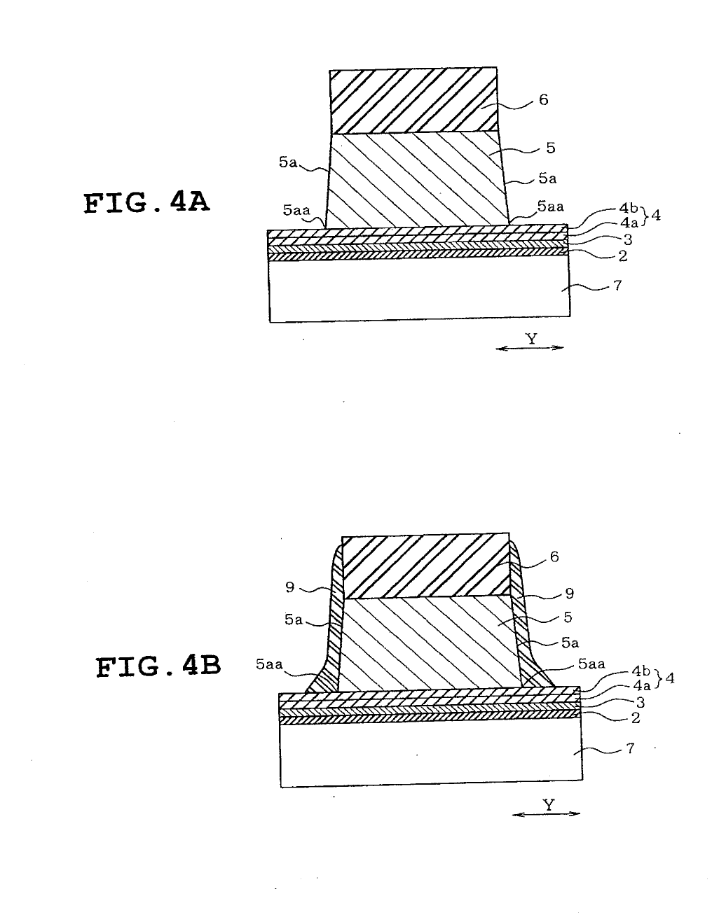

First, a monocrystal p-type silicon substrate for example is prepared to serve as semiconductor substrate 7. Above semiconductor substrate 7, tunnel insulating film 2, silicon film 3 doped with impurities, and charge trap layer 4 are formed one after another in contact with one another as illustrated in FIG. 2A to FIG. 2C. Further, control electrode 5 is formed so as to contact the upper surface of charge trap layer 4 as illustrated in FIG. 3A.

Tunnel insulating film 2 may be formed by thermally oxidizing the surface of semiconductor substrate 7. Further, polysilicon film 3, charge trap layer 4, control electrode 5, and cap film 6, when formed of the materials described earlier, may each be formed by CVD (Chemical Vapor Deposition) or the like. Silicon film 3 is later polycrystallized and transformed into a polysilicon film.

As illustrated in FIG. 3B, resist R is coated above cap film 6 and resist R is thereafter patterned by lithography. In an alternative embodiment, a smaller mask pattern may be formed using pattern forming methods such as the so-called sidewall transfer technique. Then, using the patterned resist R as a mask, cap film 6 is patterned by anisotropic dry etching using RIE (Reactive Ion Etching).

After removing resist R, control electrode 5 is etched by RIE using cap film 6 as a mask as illustrated in FIG. 4A. The etch recipe may be controlled so that sidewall 5a of control electrode 5 is positively tapered.

Then, reactive gas for producing deposit 9 is introduced into the chamber (not shown) of an RIE apparatus to cause deposit 9 along sidewall 5a of control electrode 5 and above a portion of the upper surface of charge trap layer 4. The deposition may be carried out under conditions using a gas mixture including 100 [sccm] of boron trichloride (BCl₃) and 30 [sccm] of methane (CH₄).

Other conditions applied in the deposition include pressure of 7 [mTorr], 1000 [W] of RF (radio frequency) power, and 100 [W] of RF bias power. The RF bias power is applied in pulses which may have a pulse frequency of 200 [Hz]. The percentage of Time T_on[s], in which the bias power is applied, may be configured to occupy 30 [%] of pulse period T [s] (duty cycle=T_on/T×100[%]=30[%]). The duty cycle may be reduced to increase the thickness of deposit 9, and increased to reduce the thickness of deposit 9.

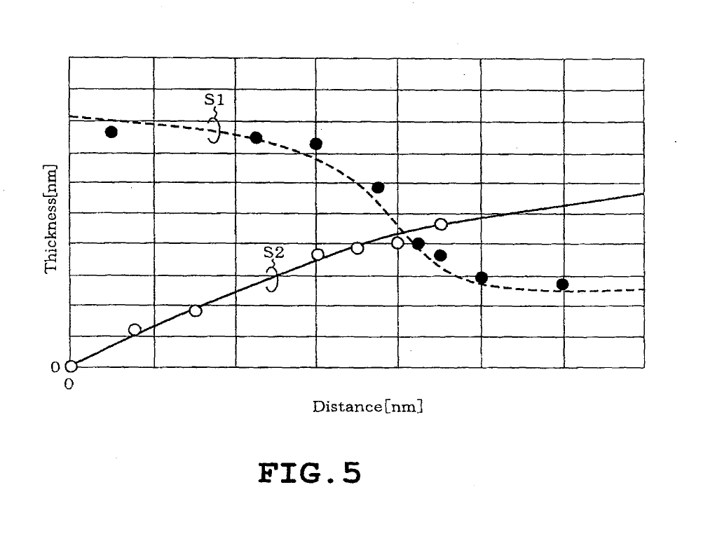

The line represented by “S1” in the chart depicted in FIG. 5 indicate the relation between the distance from lower end 5aa (pattern edge) of sidewall 5a of control electrode 5 and the thickness of deposit 9. The “distance” is taken along the latitudinal axis and the “thickness” is taken along the longitudinal axis. As indicated by “S1” in the chart of FIG. 5, deposit 9 is the thickest at the lower end 5aa (pattern edge) of sidewall 5a of control electrode 5 and becomes thinner as the lateral distance becomes greater.

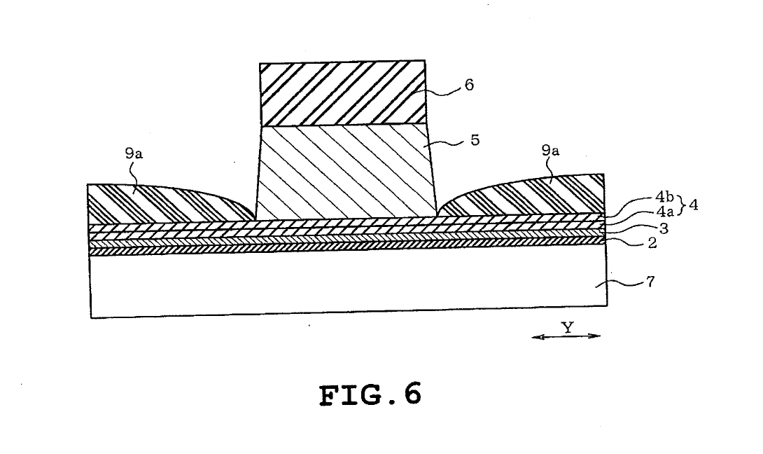

The line represented by “S2” in the chart depicted in FIG. 5 indicate the thickness of deposit 9a of a comparative example in which a generally known gas conditions are applied. More specifically, “S2” in the chart depicted in FIG. 5 results from the use of silicon chloride (SiCl₄) and oxygen (O₂) As indicated by “S2” in the chart depicted in FIG. 5, deposit 9a hardly occurs near lower end 5aa of sidewall 5a of control electrode 5. FIG. 6 schematically illustrates the resulting deposition 9a.

In the first embodiment, deposit 9 is formed under conditions to attach more easily to sidewall 5a of control electrode 5 as compared to the upper surface of charge trap layer 4 as illustrated in FIG. 4B. As a result, the area of deposit 9 attachment along sidewall 5a of control electrode 5 can be made greater than the area of deposit 9 attachment along charge trap layer 4. At this instance, it is possible to form deposit 9 so as to cover the entire surface of sidewall 5a of control electrode 5 and to further extend laterally so as to become thinner as the lateral distance from lower end 5aa of sidewall 5a of control electrode 5 becomes greater for example.

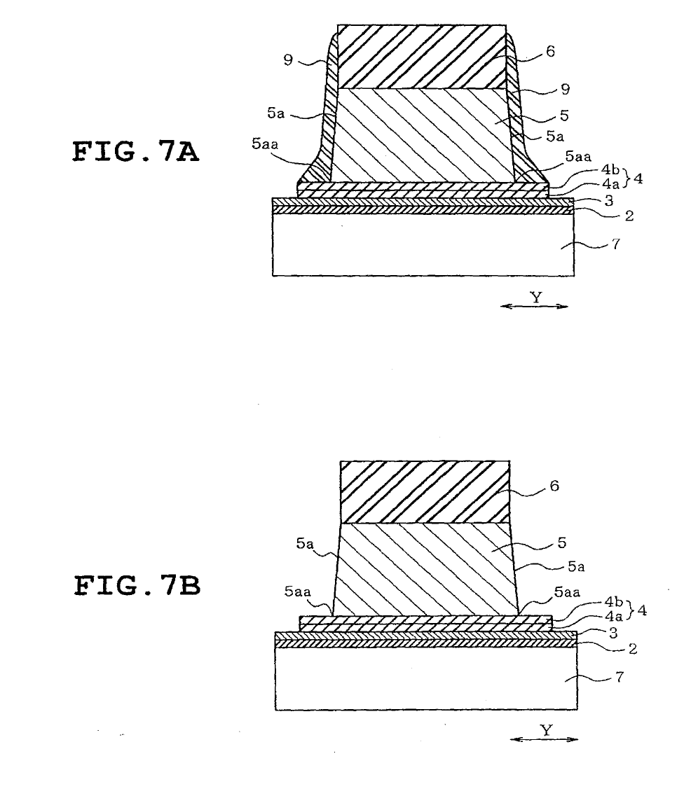

Then, as illustrated in FIG. 7A, charge trap layer 4 is anisotropically etched by RIE while allowing deposit 9 to remain. One example of etching conditions applied in this process step may include the use of a gas mixture including 100 [sccm] of boron trichloride (BCl₃) and 100 [sccm] of argon (Ar), 1000 [W] of RF power, and 100 [W] of RE bias power.

As a result, etching of charge trap layer 4 does not progress in portions where thick deposit 9 is attached (that is, near lower end 5aa of sidewall 5a, in other words, near the pattern edge) since deposit 9 serves as a mask. In contrast, in portions distanced from the pattern of control electrode 5, etching of charge trap layer 4 progresses after deposit 9 is etched away since deposit 9 is thin in such portions. As a result, the anisotropic etching progresses only or at least more aggressively in the portions where deposit 9 is thin, thereby allowing charge trap layer 4 to remain in portions where deposit 9 is thick.

Remainder deposit 9 is illustrated in FIG. 7A for ease of understanding, however, deposit 9 is substantially removed at the end of the anisotropic etching. It is thus, possible for charge trap layer 4 to remain laterally to a predetermined distance from lower end 5aa of sidewall 5a of control electrode 5 as illustrated in FIG. 7B.

Then, as illustrated in FIG. 1, silicon film 3 is anisotropically etched by RIB. Silicon film 3 may be anisotropically etched using an HBr gas. By applying a higher etching selectivity for silicon relative to an oxide film for example, silicon film 3 can be anisotropically etched using tunnel insulating film 2 as a stopper. Thus, it is possible to stop the anisotropic etching on the upper surface of tunnel insulating film 2 or for example midway into tunnel insulating film 2.

Thus, by using deposit 9, it is possible to make the Y direction length of charge trap layer 4 at the top of charge trap layer 4 to be greater than the length of control electrode 5 in the gate-length direction at the bottom of control electrode 5. Features such as the distance in which charge trap layer 4 laterally projects from the sidewall of control electrode 5 and the shape of the stepped structure of charge trap layer 4 at the side end portion of charge trap layer 4 can be controlled through adjustment of parameters such as deposition time (duty ratio) of deposit 9 and flow amounts of various gases. Then, impurities are introduced in a self-aligned manner by ion implantation and thereafter thermally treated to form diffusion layer 8.

When the sidewall of charge trap layer 4 is formed so as to be coplanar with the side wall of control electrode 5, and charge trap layer 4 is thereafter exposed to oxidizing conditions, the sidewall of charge trap layer 4 may deteriorate and consequently cause deterioration of the properties of transistor 1. However, in the first embodiment, the sidewall of the charge trap layer 4 is formed so as to laterally project with respect to the sidewall of control electrode 5. Thus, even if charge trap layer 4 is exposed to oxidizing conditions such as the thermal treatment for activating the introduced impurities performed later in the manufacturing process flow, the portion which may deteriorate by the oxidation would be the projected portion of charge trap layer 4. Thus, especially the central portion of charge trap layer 4 in the gate-length direction is not negatively affected by the oxidation. As a result, it is possible to prevent deterioration of the properties of transistor 1.

In the manufacturing process flow of the first embodiment, charge trap layer 4 is etched after at least a portion or all of sidewall 5a of control electrode 5 is masked by deposit 9. Thus, it is possible to selectively and anisotropically etch charge trap layer 4 located in portions laterally distanced from lower end 5aa of sidewall 5a of control electrode 5. Hence, it is possible to minimize the negative influence of oxidation to the side end portions of charge trap layer 4 even if thermal treatment or the like is performed later in the manufacturing process flow, and prevent especially the central portion of charge trap layer 4 in the gate-length direction from being negatively affected by the oxidation. As a result, it is possible to prevent deterioration of the properties of transistor 1.

### Second Embodiment

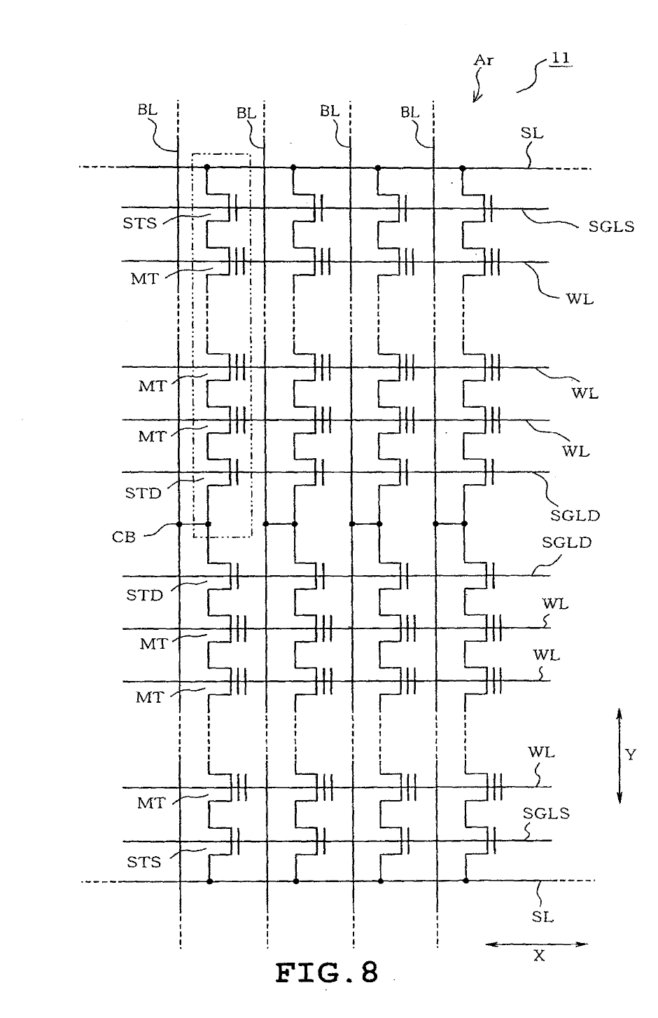

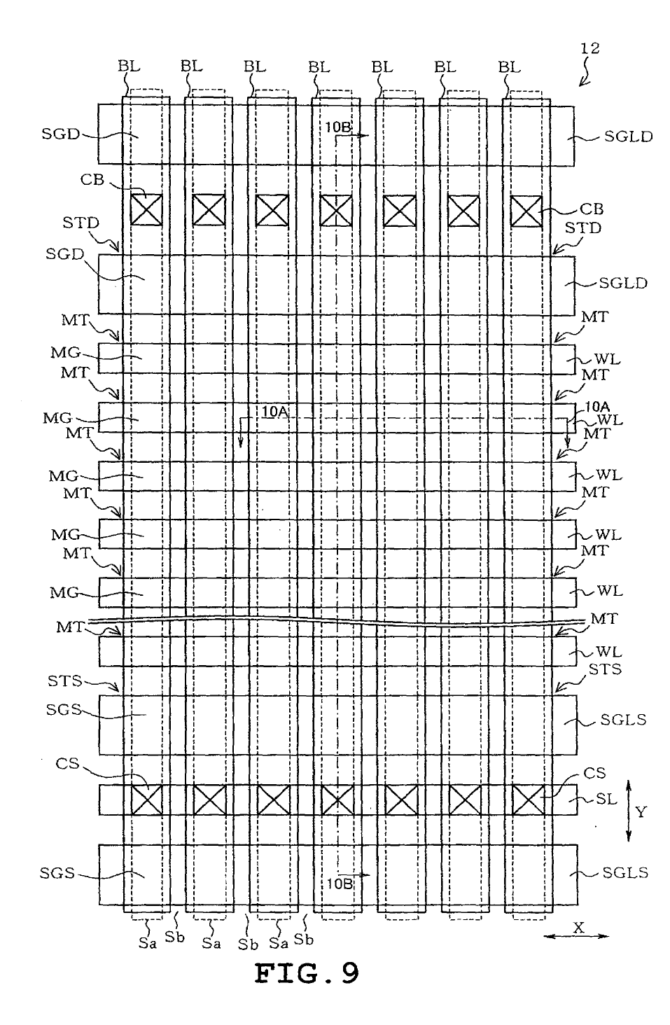

FIG. 8 to FIG. 15 illustrate a second embodiment. The second embodiment, is described through an example of a NAND flash memory device application.

FIG. 8 is one example of a block diagram schematically illustrating the electrical configuration of the NAND flash memory device. As illustrated in FIG. 8, NAND flash memory device 11 is one example of a nonvolatile semiconductor storage device and is provided with memory-cell array Ar configured by multiplicity of memory cells arranged in a matrix.

Memory-cell array Ar disposed in memory-cell region M includes multiplicity of cell units UC. One or more select transistors STD is provided in the bit line BL side of cell unit UC, and one or more select transistors STS is provided in the source line SL side of cell unit UC.

Between select transistors STD and STS, m number (m=2^{k}, m=64 for example) of cell transistors MT are series connected and serve as data storing elements. One or more dummy transistors may be provided between select transistor STD/STS and cell transistor MT. Select transistors STD and STS are configured to select a certain cell transistor MT when reading data from or writing data to such cell transistor MT.

A plurality of cell units UC aligned in the X direction form a block and memory-cell array Ar is formed by multiple of blocks aligned in the Y direction (also referred to as a gate-length direction). FIG. 8 only shows 2 blocks for simplicity.

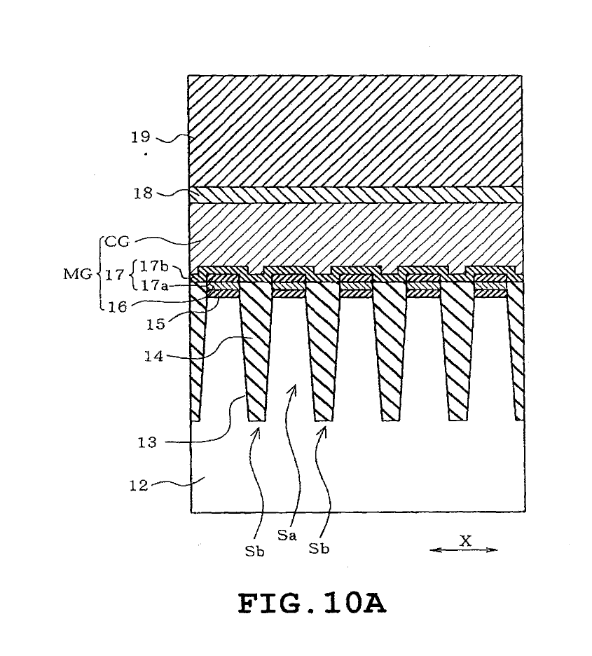

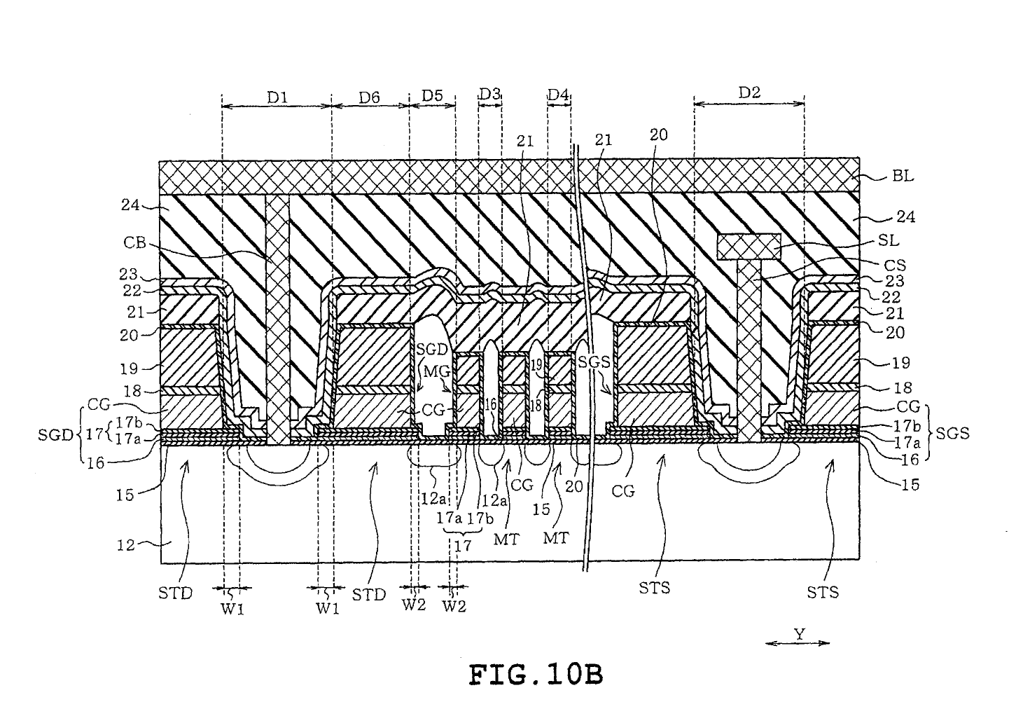

Control electrodes CG (gate MG: illustrated in FIG. 10A) of cell transistors MT disposed in multiple cell units UC aligned in the X direction are interconnected by word line WL. Control electrodes CG (select gate SGS) of select transistors STS disposed in multiple cell units UC aligned in the X direction are interconnected by select gate line SGLS. Control electrodes CG (select gate SGD) of select transistors STD disposed in multiple cell units UC aligned in the X direction are interconnected by select gate line SGLD.

Bit line BL is electrically connected, via bit-line contacts CB, to diffusion layers located beside select transistors STD disposed in multiple cell units SC aligned in the Y direction. Source line SL is electrically connected, via source-line contacts CS, to diffusion layers located beside select transistors STS disposed in multiple cell units UC aligned in the X direction.

FIG. 9 is one example of a plan view schematically and partially illustrating the layout of a block in the memory-cell region. A silicon substrate for example is used as semiconductor substrate 12. Element isolation regions Sb taking an STI (Shallow Trench Isolation) structure are formed into semiconductor substrate 12 along the Y direction as viewed in FIG. 9. Element isolation regions Sb isolate element regions Sa of cell units UC in the X direction as viewed in FIG. 9. Thus, element regions Sa are isolated in the X direction from one another by element isolation regions Sb and extend in the Y direction.

Element regions Sa have equal X-direction width and are spaced from one another by equal X-direction distance. Bit-line contacts CB are formed so as to contact element regions Sa of each of cell units UC. Further, source-line contacts CS are formed so as to contact element regions Sa of each of cell units UC.

As illustrated in FIG. 8 and FIG. 9, each of bit lines BL extend in the Y direction and are spaced from one another in the X direction. Bit lines BL have equal X-direction width and are spaced from one another by equal X-direction distance. Source lines SL, on the other hand, extend along the X direction above source-line contacts CS of multiple cell units UC.

Next, a description will be given on examples of cross-sectional structures of a select transistor and a cell transistor of the first embodiment. FIG. 10A is one schematic example of a cross-sectional view taken along line 10A-10A running along word line WL (X direction: channel width direction) as viewed in FIG. 9. FIG. 10B is one schematic example of a cross-sectional view taken along line 10B-10B running along bit line BL (Y direction: channel length direction) as viewed in FIG. 9.

In the example illustrated in FIG. 10A, a p-type monocrystal silicon substrate for example is used as semiconductor substrate 12. Element isolation trenches 13 are formed into semiconductor substrate 12. Element isolation trenches 13 extend in the Y direction are spaced from one another in the X direction. Element isolation trenches 13 isolate element regions Sa in the X direction. Element isolation trenches 13 are filled with element isolation film 14 to form element isolation regions Sb taking an STI structure.

Tunnel insulating film 15 is disposed above element regions Sa isolated by element isolation regions Sb. Gate MG is disposed above tunnel insulating film 15. Gate MG is provided with polysilicon film 16, charge trap layer 17, and control electrode CG. Cap film 18 is disposed in contact with the upper surface of control electrode CG. Hard mask 19 is disposed above the upper surface of cap film 18.

Tunnel insulating film 15, polysilicon film 16, charge trap layer 17, control electrode CG and cap film 18 of the second embodiment correspond to insulating film 2, polysilicon film 3, charge trap layer 4, control electrode 5 and cap film 6 of the first embodiment. Thus, charge trap layer 17 may be considered to include trap layer 17a and block layer 17b.

Polysilicon film 16 is disposed in contact with the upper surface of tunnel insulating film 15. Trap layer 17a of charge trap layer 17 is disposed in contact with the upper surface of polysilicon film 16. Block layer 17b extends along the upper surface and the sidewall of trap layer 17a and further extends in the X direction across the upper surfaces of element isolation films 14.

As illustrated in FIG. 10B, gates MG of cell transistors MT are aligned in the Y direction. In one side of the group of gates MG, select gate SGD of select transistor STD is disposed so as to be spaced from the group of gates MG. In the other side of the group of gates MG, select gate SGS of select transistor STS is disposed so as to be spaced from the group of gates MG.

Gates MG are electrically isolated from one another by trenches (not represented by reference symbols) provided for gate isolation. Gate MG and gate SGD as well as date MG and gate SGS are isolated from one another in the similar manner. Air gaps are defined in the trenches to prevent the gates from interfering with one another. In an alternative embodiment, the trenches may be filled with interlayer insulating film 21 (illustrated in FIG. 10B) including for example a silicon oxide film formed of TECHS (tetraethyl orthosilicate).

Interlayer insulating film 21 is formed above gates MG, SGD, and SGS via protective film 20. The stack structures of select gates SGD and SGS are substantially identical to those of gates MG of cell transistors MT. Protective film 20 is formed along the sidewalls of select gates SGD and SGS and along the sidewalls of gates MG to provide protection to the sidewalls of gates SGD, SGS, and MG.

Above, interlayer insulating film 21, silicon oxide film 22 and silicon nitride film 23 are stacked one after another and interlayer insulating film 24 is further formed above silicon nitride film 23. Interlayer insulating film 24 is formed of for example a silicon oxide film.

In the surface layer of semiconductor substrate 12 located between gate electrodes MG, between gate electrodes SGD and MG, and between gate electrodes SGS and MG, diffusion layers 12a are formed. Diffusion layer 12a is an impurity diffusion layer doped with n-type impurities such as phosphorous (P) and/or arsenic (As) or p-type impurities such as boron (B) by ion implantation. Annealing is thereafter performed to activate the implanted impurities.

As illustrated in FIG. 10B, bit-line contact CB is disposed between select gates SGD and source-line contact CS is disposed between select gates SGS.

Bit-line contact CB extends through interlayer insulating film 24, silicon nitride film 23, and silicon oxide film 22 formed between select gates SGD and establishes contact with the upper surface of semiconductor substrate 12. Bit line BL is formed above interlayer insulating film 24.

Bit line BL is configured to contact the upper surface of bit-line contact CB. Further, source-line contact CS extends through interlayer insulating film 24, silicon nitride film 23, and silicon oxide film 22 formed between select gates SGS and establishes contact with the upper surface of semiconductor substrate 12.

The sidewall of control electrode CG of select gate SGD facing bit-line contact CB is formed as an inclined surface. Similarly, the sidewall of control electrode CG of select gate SGS facing source-line contact CS is formed as an inclined surface.

Spacing D1 between the lower ends of the sidewalls of control electrodes CG of select gates SGD, and spacing D2 between the lower ends of the sidewalls of control electrodes CG of select gates SGS are configured to be greater than width D4 of gate MG of cell transistor MT. Further spacing D3 between gates MG is configured to be less than width D4 of gate MG. Still further, spacing D5 between select gate SGD and gate MG is configured to be greater than width D4 of gate MG and greater than spacing D3 between gates MG.

Further, spacing D1 between select gates SGD of adjacent blocks are configured to be greater than spacing D5 between gates SGD and MG. Still further, spacing D1 between select gates SGD of adjacent blocks are configured to be substantially equal to width D6 of select gate SGD.

Further, in the region between select gates SGD of the adjacent blocks, the top portion of silicon film 16 and the top portion of charge trap layer 17 project in the Y direction from the lateral end of the bottom portion of control electrode CG by width W1.

In contrast, in the region between gates SGD and MG, the top portion of silicon film 16 and the top portion of charge trap layer 17 project in the Y direction from the lateral end of the bottom portion of control electrode CG by width W2. Projecting width W1 is greater than projecting width W2 (W1>W2).

In the region between gates MG, silicon film 16 and charge trap layer 17 may project, but do not have to project in the Y direction from the lateral end of the bottom portion of control electrode CG. In case silicon film 16 and charge trap layer 17 do project in the Y direction, for example by width W3 (not illustrated), this width W3 is less than width W2 when spacing D3 between gates MG is less than spacing D5 between gates SGD and MG. The second embodiment is described through an example in which silicon film 16 and charge trap layer 17 do not project as illustrated in FIG. 10B.

Next, a description will be given on one example of a manufacturing process flow of the structure described above. The following description will focus on the features of the second embodiment. However, process steps that are required for implementation or that are known may be further incorporated between the process steps discussed below. Further, the discussed process steps may be rearranged if practicable.

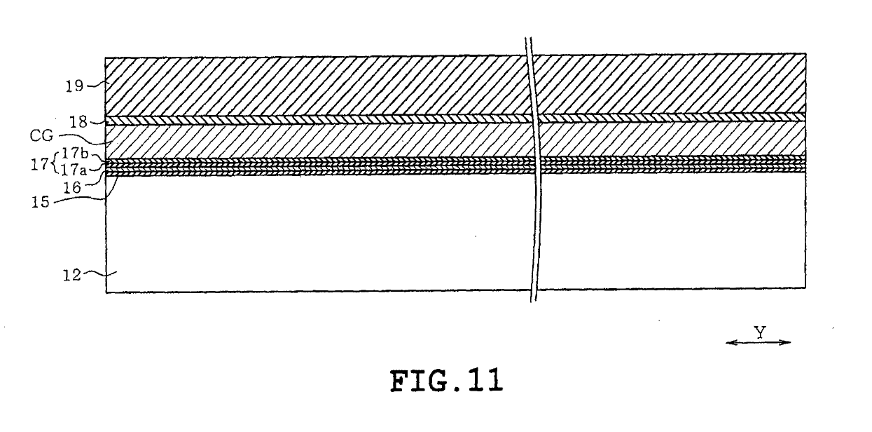

A brief description is given hereinunder on the manufacturing process flow for obtaining the cross-sectional structure illustrated in FIG. 11. First, a monocrystal p-type silicon substrate for example is prepared to serve as semiconductor substrate 12. Then, a silicon oxide film for example serving as tunnel insulating film 15 is formed on the surface of semiconductor substrate 12 by thermal oxidation.

Tunnel insulating film 15 is formed so as to serve as a gate insulating film of cell transistor MT. Silicon film 16 is formed for example by CVD so as to contact the upper surface of tunnel insulating film 15. Silicon film 16 is amorphous when formed but is later polycrystallized by thermal treatment.

Above the upper surface of silicon film 16, the lower layer portion (trap layer 17a for example) of charge trap layer 17 is formed by CVD. Then, a resist (not shown) is coated over the lower layer portion and patterned by lithography to form a mask pattern. Using the mask pattern as a mask, element isolation trenches 13 are formed into trap layer 17a, silicon film 16, tunnel insulating film 15, and the upper portion of semiconductor substrate 12 to form a line-and-space pattern.

Element isolation trenches 13 are filled with element isolation film 14 formed for example by CVD or coating. The upper portion of element isolation film 14 is planarized or etched back to partially or entirely expose trap layer 17a. Then, the upper layer portion (block layer 17b for example) of charge trap layer 17 is formed for example by LP-CVD along the upper surface and the upper side surfaces of the lower layer portion (trap layer 17a for example) of charge trap layer 17 and along the upper surface of element isolation film 14.

Thereafter, control electrode CG is formed above the upper surface of charge trap layer 17 by stacking low-resistance metal such as tungsten (W) via barrier metal. Cap film 18 and hard mask 19 are further stacked in the listed sequence by CVD.

FIG. 11 illustrates the above described structure through the Y-direction cross-section taken along line 10B-10B of FIG. 9. The Y-direction cross section as this stage has tunnel insulating film 15, silicon film 16, charge trap layer 17, control electrode CG, cap film 18, and hard mask 19 stacked one after another in the listed sequence above semiconductor substrate 12.

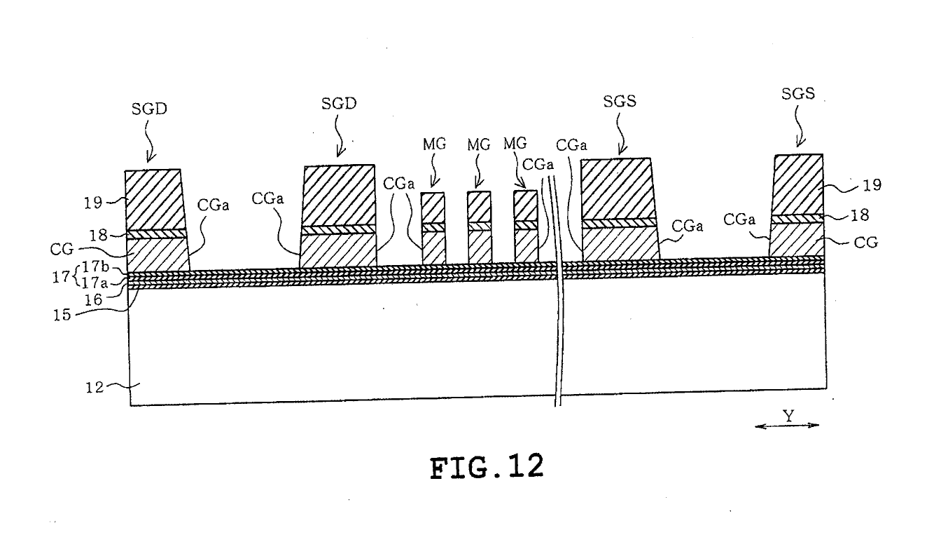

As illustrated in FIG. 12, a resist (not shown) is formed above the upper surface of hard mask 19 and patterned into a resist pattern. Using the resist pattern as a mask, hard mask 19 and cap film 18 are anisotropically etched by RIE. After removing the resist pattern, control electrode CS is further anisotropically etched by RIE. The etching is temporarily stopped on the upper surface of charge trap layer 17. At this instance, sidewalls CGa of control electrodes CG of select gates SGD and SGS are processed into inclined surfaces.

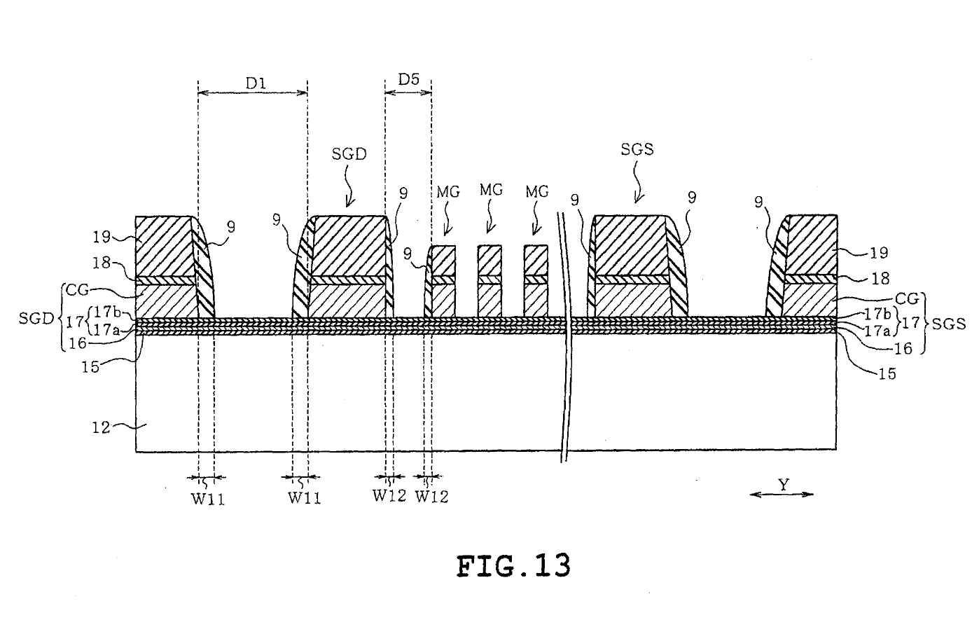

Deposits 9 described in the first embodiment are deposited along sidewalls CGa of control electrodes CG of gates SGD, SGS, and MG, and so as to extend further beyond the lower ends of sidewalls CGa of control electrodes CG so as to cover a portion of each of the upper surfaces of charge trap layers 17. Deposits 9 are deposited along a portion of each of the upper surfaces of charge trap layers 17 located beside control electrodes CG, but not in the central portions of the gaps between gate SGD and gate MG, between gates MG, and between gates MG and gate SGS. Because it is difficult for the reaction gas to move into narrow regions such as the gaps between the gates (such as the gaps between gates MG), deposits 9 do not easily deposit in such regions as illustrated in FIG. 13.

Thus, deposits 9 easily attach in a protruding manner along sidewalls CGa of control electrodes CG located in the gaps between select gates SGD, but do not easily attach along sidewalls CGa of control electrodes CG located in the gaps between gates MG. FIG. 13 does not illustrate any deposits 9 along sidewalls CGa of control electrodes CG located in the gaps between gates MG for easier understanding, but a slight amount of deposits 9 may deposit along sidewalls CGa of control electrodes CG located in gate MG gaps.

In the region between adjacent select gates SGD, lower side ends of control electrodes CG are spaced by spacing D1 which is greater than spacing D5 between the lower side ends of control electrodes CG of select gate SGD and gate MG. Thus, the width of lateral deposit attachment along the upper surface of charge trap layer 17 taken from the lower side ends of control electrode CG is represented as first width W11 in the region between select gates SGD and as second width W12 in the region between gates SGD and MG (W12<W11).

Next, charge trap layer 17 and silicon film 16 are anisotropically etched one after another by RIE. Because deposit 9 serves as a mask, etching does not progress in the portions of charge trap layer 17 covered by deposit 9 unlike the portions of charge trap layer 17 not covered by deposit 9 in which etching progresses.

Etching of charge trap layer 17 uncovered by deposit 9 and etching of deposit 9 progress simultaneously and deposit 9 is removed. After deposit 9 is removed, the exposed surface of charge trap layer 17 is subjected to etching. When the anisotropic etching of the uncovered charge trap layer 17 reaches the upper surface of tunnel insulating film 15, the charge trap layer 17 having been covered by deposit 9 remains from the lower ends of sidewalls CGa of control electrode CG to portions distanced laterally in the Y direction so as to be separated at the central portions of the gaps between gates SGD, between gates SGD and MG, between gates MG, between gate SGS and MG, and between gates SGS. The etching conditions are thereafter modified to etch silicon oxide film 16. Deposit 9 almost entirely etched away by the above described etching.

In the manufacturing phase illustrated in FIG. 13, width W11 of deposit 9 attachment between gates SGD is greater than width W12 of deposit 9 attachment between gates SGD and MG. Thus, when charge trap layer 17 and silicon film 16 are anisotropically etched, width W1 of projection of charge trap layer 17 and silicon film 16 between gates SGD becomes greater than width W2 of projection of charge trap layer 17 and silicon film 16 between gates SGD and MG.

Then, n-type impurities (such as phosphorous (P), arsenic (As)) and/or p-type impurities (such as boron (B)) are selectively doped by ion implantation into the regions between gates MG, between gates SGD and MG, between gates SGS and MG, in regions for forming bit-line contacts CB, and in regions for forming source-line contacts CS. The impurity profiles in each of the regions are controlled to their target profiles.

Parameters such as ion implantation energy, tilt angles relative to the substrate surface, and the like are altered when implanting various types of impurities between gates MG, between, gates SGD, and between gates MG and SGD. For example, impurities (p-type impurities for example) having the same conductive type as semiconductor substrate 12 are implanted obliquely especially into the region below the lower ends of the sidewalls of select gates SGD and SGS where electric field is prone to concentrate. This is intended to form concentration gradient in the depth direction and the Y direction of semiconductor substrate 12 when doping impurities by ion implantation.

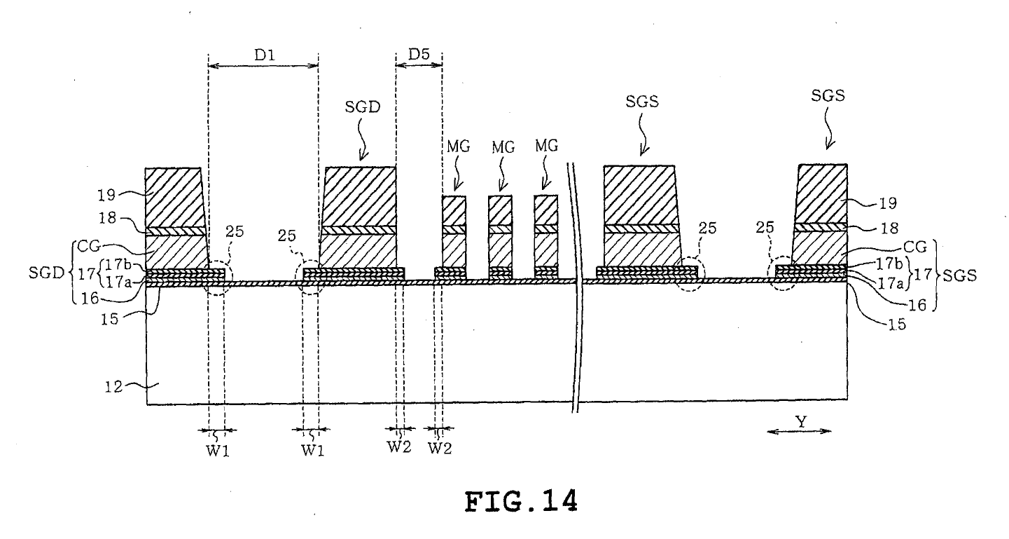

Charge trap layer 17 and silicon film 16 are configured to project laterally from sidewalls CGa of control electrode CG in the process steps preceding the ion implantation process step. Thus, steps (illustrated in FIG. 14) produced by projecting portions 25 of charge trap layer 17 and silicon film 16 can be utilized in doping impurities into semiconductor substrate 12 with concentration gradient by ion implantation. It is thus, possible to properly control the concentration gradient of the impurities and maintain the target impurity profile.

Then, as illustrated in FIG. 10B, protection film 20 for protecting the sidewalls of select gates SGD and SGS and gates MG are formed for example of a silicon oxide film. Further, interlayer insulating film 21 is deposited by plasma CVD so as to provide unfilled gaps between gates SGD and MG, between gates SGS and MG, and between gates MG. It is thus, possible to provide unfilled gaps between gates SGD and MG, between gates SGS and MG, and between gates MG.

Above interlayer insulating film 21, silicon oxide film 22 and silicon nitride film 23, serving as liner films, are formed one after another which is followed by a deposition of another interlayer insulating film 24 by CVD. Contact holes are formed through insulating films 22, 23, and 24 to form bit-line contacts CB and source-line contacts CS in the contact holes. Upper layer wirings such as source lines SL and bit lines BL are formed thereafter.

In the manufacturing process flow of the second embodiment, silicon film 16 and charge trap layer 17 are configured to project laterally from sidewalls CGa of the bottom portion of control electrode CG. Thus, it is possible to increase the volume of silicon film 16 and charge trap layer 17 even when the dimensions of elements (silicon film 16 and charge trap layer 17 for example) such as the width in the gate-width direction and the thickness in the height direction are shrunk to form flat cells under the influence of recent microfabrication of elements. Thus, even if the lateral ends of silicon film 16 and charge trap layer 17 partially deteriorate by being subjected to severe conditions such as oxidation, the central portions of silicon film 16 and charge trap layer 17 remain in good condition and therefore allows inhibits deterioration of elements.

Deposit 9 is deposited along sidewalls CGa of control electrode CG before charge trap layer 17 and polysilicon film 16 are anisotropically etched. Thus, it is possible to configure charge trap layer 17 and polysilicon film 16 to laterally project from sidewalls CGa of control electrode CG. As a result, steps produced by projecting portions 25 of charge trap layer 17 and silicon film 16 can be utilized in properly controlling the concentration gradient of the doped impurities and thereby maintain the target impurity profile of impurities in semiconductor substrate 12.

### (Further Modifications)

The claims describe examples of concepts derivable from high-level, mid-level, or low-level abstractions of the configurations of the foregoing embodiments or modified embodiments; or from combinations of some or all of the configurations of the foregoing embodiments or modified embodiments. Alternatively, the concepts may be described as follows.

### [Aspect 1]

One aspect including:

forming a tunnel insulating film so as to contact a semiconductor substrate;

forming a charge trap layer above the tunnel insulating film including a trap layer configured to trap charge and a block layer configured to block penetration of electrons;

forming a control electrode so as to contact the charge trap layer;

anisotropically etching the control electrode to expose a sidewall of the control electrode;

depositing a deposit so as to be attached to a surface of the sidewall of the control electrode exposed by the etching, such that an area of the deposit attached to the surface of the sidewall of the control electrode exposed by the etching is greater than an area of the deposit attached to the charge trap layer; and

anisotropically etching the charge trap layer using the deposit as a mask so that the charge trap layer projects in a gate-length direction from a lower end of the sidewall of the control electrode and a sidewall of the charge trap layer is exposed.

### [Aspect 2]

One aspect including:

forming a tunnel insulating film so as to contact a semiconductor substrate;

forming a charge trap layer above the tunnel insulating film including a trap layer configured to trap charge and a block layer configured to block penetration of electrons;

forming a control electrode so as to contact the charge trap layer;

anisotropically etching the control electrode to expose a sidewall of the control electrode;

depositing a deposit so as to be attached to a surface of the sidewall of the control electrode exposed by the etching;

anisotropically etching the charge trap layer using the deposit as a mask so that the charge trap layer projects in a gate-length direction from a lower end of the sidewall of the control electrode and a sidewall of the charge trap layer is exposed; and

introducing impurities having a conductivity type identical to a conductivity type of the semiconductor substrate at a tilted angle into a region below a lower end of the sidewall of the charge trap layer.

### [Aspect 3]

One aspect including:

a semiconductor substrate; and

a transistor including:
a tunnel insulating film disposed in contact with the semiconductor substrate
a charge trap layer disposed above the tunnel insulating film and formed of a stack including a trap layer configured to trap charge and a block layer configured to prevent penetration of electrons; and
a control electrode disposed in contact with the charge trap layer,
the charge trap layer of the transistor having a sidewall projecting laterally along a gate-length direction of the control electrode from a lower end of a sidewall of the control electrode located in the gate-length direction,
a surface of the sidewall the control electrode being positively tapered such that a width of the control electrode taken along a gate-length direction becomes narrower toward an upper side of the control electrode from a lower side of the control electrode.

### [Aspect 4]

One aspect including:

a semiconductor substrate; and

a select transistor including:
a tunnel insulating film disposed in contact with the semiconductor substrate,
a charge trap layer disposed above the tunnel insulating film and formed of a stack including a trap layer configured to trap charge and a block layer configured to prevent penetration of electrons; and
a control electrode disposed in contact with the charge trap layer,
the charge trap layer of the select transistor having a sidewall projecting laterally along a gate-length direction of the control electrode from a lower end of a sidewall of the control electrode located in the gate-length direction.

### [Aspect 5]

One aspect including:

a semiconductor substrate; and

a cell transistor including:
a tunnel insulating film disposed in contact with

the semiconductor substrate,
a charge trap layer disposed above the tunnel insulating film and formed of a stack including a trap layer configured to trap charge and a block layer configured to prevent penetration of electrons; and
a control electrode disposed in contact with the charge trap layer,
the charge trap layer of the cell transistor having a sidewall projecting laterally along a gate-length direction of the control electrode from a lower end of a sidewall of the control electrode located in the gate-length direction.

### [Aspect 6]

One aspect including:

a semiconductor substrate; and

a first transistor, a second transistor, and a third transistor, including:
a tunnel insulating film disposed in contact with the semiconductor substrate;
a charge trap layer disposed above the tunnel insulating film and formed of a stack including a trap layer configured to trap charge and a block layer configured to prevent penetration of electrons; and
a control electrode disposed in contact with the charge trap layer,
the control electrode of the first transistor and the control electrode of the second transistor disposed adjacent to the control electrode of the first transistor are spaced from one another by a first spacing,
the control electrode of the third transistor and the control electrode of the second transistor disposed adjacent to the control electrode of the third transistor are spaced from on another by a second spacing less than the first spacing,

the charge trap layer of the second transistor has a first sidewall facing the first transistor projecting laterally by a first distance along a gate-length direction of the control electrode of the second transistor from a lower end of a sidewall of the control electrode of the second transistor located in the gate-length direction, and a second sidewall facing the third transistor projecting laterally by a second distance less than the first distance along the gate-length direction of the control electrode of the second transistor from a lower end of a sidewall of the control electrode located in the gate-length direction.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of nonvolatile semiconductor storage device comprising:
forming a tunnel insulating film so as to contact a semiconductor substrate;
forming a charge trap layer above the tunnel insulating film including a trap layer configured to trap charge and a block layer configured to block penetration of electrons;
forming a control electrode so as to contact the charge trap layer;
anisotropically etching the control electrode to expose a sidewall of the control electrode;
depositing a deposit so as to be attached to a surface of the sidewall of the control electrode exposed by the etching; and
anisotropically etching the charge trap layer using the deposit as a mask so that the charge trap layer projects in a gate-length direction from a lower end of the sidewall of the control electrode and a sidewall of the charge trap layer is exposed.

2. The method according to claim 1, wherein the deposit comprises a boron containing material deposited by using a gas mixture including at least boron trichloride and methane.

3. The method according to claim 1, wherein the depositing is carried out by applying a radio frequency bias power in pulses and a duty cycle of the radio frequency bias power is configured to range from 10% to 100%.

4. The method according to claim 2, wherein the depositing is carried out by applying a radio frequency bias power in pulses and a duty cycle of the radio frequency bias power is configured to range from 10% to 100%.

5. The method according to claim 1, wherein the depositing and the anisotropically etching the charge trap layer using the deposit as a mask are carried out in a same process chamber.

6. The method according to claim 1, wherein an area of the deposit attached to the surface of the sidewall of the control electrode, exposed by the etching, by the depositing is greater than an area of the deposit attached to the charge trap layer by the depositing.

7. The method according to claim 1, further comprising introducing impurities having a conductivity type identical to a conductivity type of the semiconductor substrate at a tilted angle into a region below a lower end of the sidewall of the charge trap layer.

8. A nonvolatile semiconductor storage device comprising:
a semiconductor substrate; and
one or more transistors each including:
a tunnel insulating film disposed in contact with the semiconductor substrate;
a charge trap layer disposed above the tunnel insulating film and formed of a stack including a trap layer configured to trap charge and a block layer configured to prevent penetration of electrons; and
a control electrode disposed in contact with the charge trap layer,
the charge trap layer of the one or more transistors has a sidewall projecting laterally along a gate-length direction of the control electrode from a lower end of a sidewall of the control electrode located in the gate-length direction.

9. The device according to claim 8, wherein the control electrode further includes a sidewall having a positively tapered surface such that a width of the control electrode taken along a gate-length direction becomes narrower toward an upper side of the control electrode from a lower side of the control electrode.

10. The device according to claim 8, wherein the one or more transistors comprise a cell transistor configured to store data in the charge trap layer by trapping charge.

11. The device according to claim 8, wherein the one or more transistors comprises a select transistor configured to select a cell transistor when reading data from or writing data to the cell transistor.

12. The device according to claim 8, wherein a plurality of transistors are provided, the plurality of transistors including a first transistor, a second transistor, and a third transistor,
wherein the control electrode of the first transistor and the control electrode of the second transistor disposed adjacent to the control electrode of the first transistor are spaced from one another by a first spacing,
wherein the control electrode of the third transistor and the control electrode of the second transistor disposed adjacent to the control electrode of the third transistor are spaced from on another by a second spacing less than the first spacing,
wherein the charge trap layer of the second transistor has a first sidewall facing the first transistor projecting laterally by a first distance along a gate-length direction of the control electrode of the second transistor from a lower end of a sidewall of the control electrode of the second transistor located in the gate-length direction, and a second sidewall facing the third transistor projecting laterally by a second distance less than the first distance along the gate-length direction of the control electrode of the second transistor from a lower end of a sidewall of the control electrode located in the gate-length direction.

13. The device according to claim 8, wherein the charge trap layer comprises a stack of films including a high-dielectric constant film.

14. The device according to claim 13, wherein the charge trap layer comprises a stack of structures including a silicon nitride, a first hafnium-containing silicon oxide film, a silicon oxide film, and a second hafnium-containing silicon oxide film.

15. A nonvolatile semiconductor storage device comprising:
a semiconductor substrate; and
a NAND cell unit including:
select transistors each having a first width in a gate-length direction,
a cell transistor being spaced in the gate-length direction from the select transistors and having a second width in the gate-length direction less than the first width,
the select transistors and the cell transistor each having a tunnel insulating film disposed in contact with the semiconductor substrate, a charge trap layer disposed above the tunnel insulating film so as to contact the tunnel insulating film and formed of a stack including a trap layer configured to trap charge and a block layer configured to prevent penetration of electrons; and a control electrode disposed in contact with the charge trap layer,
the charge trap layer of each of the select transistors and the cell transistor have a sidewall projecting laterally along the gate-length direction of the control electrode from a lower end of a sidewall of the control electrode located in the gate-length direction.

16. The device according to claim 15, wherein the charge trap layer comprises a stack of films including a high-dielectric constant film.

17. The device according to claim 15, wherein the charge trap layer comprises a stack of structures including a silicon nitride, a first hafnium-containing silicon oxide film, a silicon oxide film, and a second hafnium-containing silicon oxide film.
